(19) United States
(12) Patent Application Publication
(10) Pub. No.: US 2015/0303212 A1
(43) Pub. Date: Oct. 22, 2015

(54) SEMICONDUCTOR MEMORY DEVICE

(71) Applicant: KABUSHIKI KAISHA TOSHIBA, Tokyo (JP)

(72) Inventors: Jun MURAKAMI, Yokkaichi Mie (JP); Koichi MATSUNO, Mei Mei (JP); Hisakazu MATSUMORI, Yokkaichi Mie (JP)

(21) Appl. No.: 14/618,248

(22) Filed: Feb. 10, 2015

Related U.S. Application Data
(60) Provisional application No. 61/981,453, filed on Apr. 18, 2014.

(51) Int. Cl. H01L 27/115; H01L 23/528; H01L 21/027; H01L 21/768; G11C 16/04; H01L 21/311

(52) U.S. Cl. CPC H01L 27/11582; G11C 16/0483; H01L 27/11556; H01L 27/1157; H01L 27/11524; H01L 21/31111; H01L 21/0271; H01L 21/768; H01L 23/528

(57) ABSTRACT

A semiconductor memory device includes a semiconductor substrate, a plurality of NAND strings each of which includes a plurality of memory cells provided on the semiconductor substrate and disposed in a first direction, and a select gate provided adjacent to the memory cell at an end portion of the plurality of memory cells, such that two select gates face each other at the ends of their respective memory cells, and a first spacer layer formed on a side wall between the select gates of the NAND strings disposed adjacent to each other. The first spacer layer includes a recess therein at the portion thereof located adjacent to the semiconductor substrate.

### CROSS-REFERENCE TO RELATED APPLICATION

This application is based upon and claims the benefit of priority from U.S. Provisional Patent Application No. 61/981,453, filed Apr. 18, 2014, the entire contents of which are incorporated herein by reference.

### FIELD

Embodiments described herein relate to a semiconductor memory device.

### BACKGROUND

In a manufacturing step of a semiconductor memory device, for example, in a manufacturing step of a NAND type flash memory, there has been known a case where a thickness of an element separating insulating film or a film formed on a semiconductor substrate is etched away during the formation of a contact structure between adjacent gate electrodes. When a film of a different material than the underlying material is formed on the underlying exposed surface, such as an element forming region of a semiconductor substrate, the differences in the internal stresses of the materials, and their coefficients of thermal expansion, can cause delamination of the contact from the underlying element forming region. Additionally, if an insulating material is formed on a proportion of the element forming region, the resistance between the contact and the element forming region is increased, leading to erratic performance of a resulting semiconductor device or even non-operability thereof.

### BRIEF DESCRIPTION OF THE DRAWINGS

FIG. 1 is one example of an equivalent circuit diagram showing a portion of a memory cell array formed in a memory cell region of a semiconductor memory device according to an embodiment.

FIG. 2 is one example of a plan view schematically showing a layout pattern of a portion of the memory cell region.

FIG. 3A to FIG. 10A are one examples of longitudinal cross-sectional views taken along a line 3-3 in FIG. 2.

FIG. 3B to FIG. 10B are one examples of longitudinal cross-sectional views taken along a line 4-4 in FIG. 2.

FIG. 11 is one example of a longitudinal cross-sectional view according to a first modification.

FIG. 12A and FIG. 12B are one examples of longitudinal cross-sectional views according to a second modification.

### DETAILED DESCRIPTION

In general, according to an embodiment, a semiconductor memory device includes a semiconductor substrate, a plurality of NAND strings each of which includes a plurality of memory cells provided on the semiconductor substrate and disposed in a first direction, and a select gate provided adjacent to the memory cell at an end portion of the plurality of memory cells, such that two select gates face each other at the ends of their respective memory cells, and a first spacer layer formed on a side wall between the select gates of the NAND strings disposed adjacent to each other. The first spacer layer includes a recess therein at the portion thereof located adjacent to the semiconductor substrate.

### Embodiment

Hereinafter, the explanation is made with respect to an embodiment where a NAND type flash memory device is used as a semiconductor memory device with reference to the drawings. In the explanation made hereinafter, elements having identical functions or identical configurations are given the reference numerals or letters. The drawings are schematic views and hence, the relationship between thicknesses and sizes in a plane, a ratio of the thicknesses of the respective layers and the like, are not always equal to those of an actual semiconductor memory device. Further, also with respect to the directions (“up”, “down”, “left” and “right”), these directions are the relative directions when a circuit forming surface side of a semiconductor substrate described later is set as an upper side, and these directions do not always agree with directions determined with reference to the direction of gravitational acceleration. In the explanation made hereinafter, for the sake of convenience of the explanation, an XYZ orthogonal coordinate system is used. In such an orthogonal coordinate system, two directions which are parallel to a surface of a semiconductor substrate and are orthogonal to each other are assumed as the X direction and the Y direction. The direction orthogonal to both the X direction and the Y direction is assumed to be the Z or “up” direction.

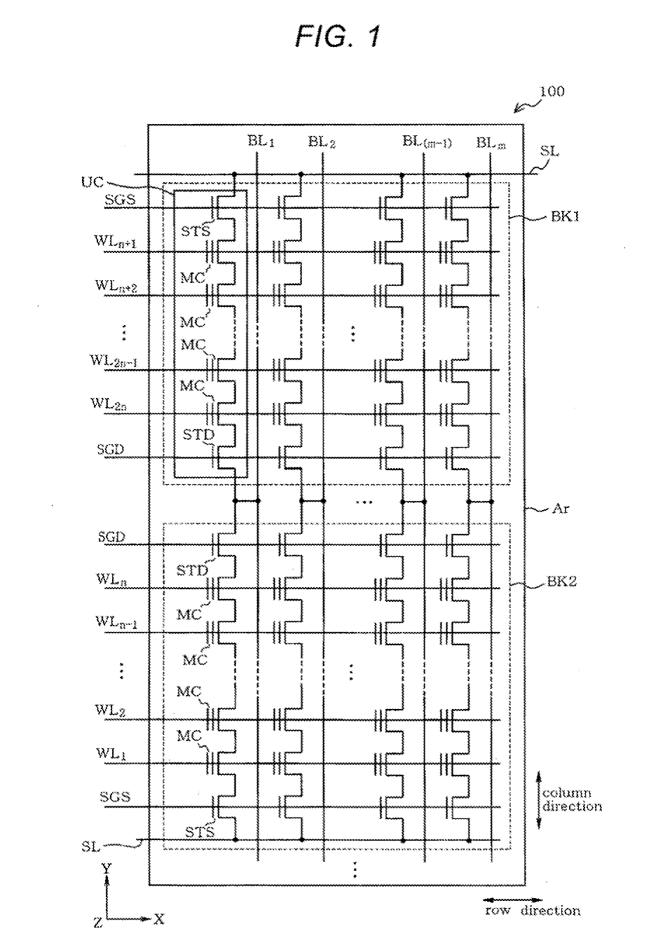

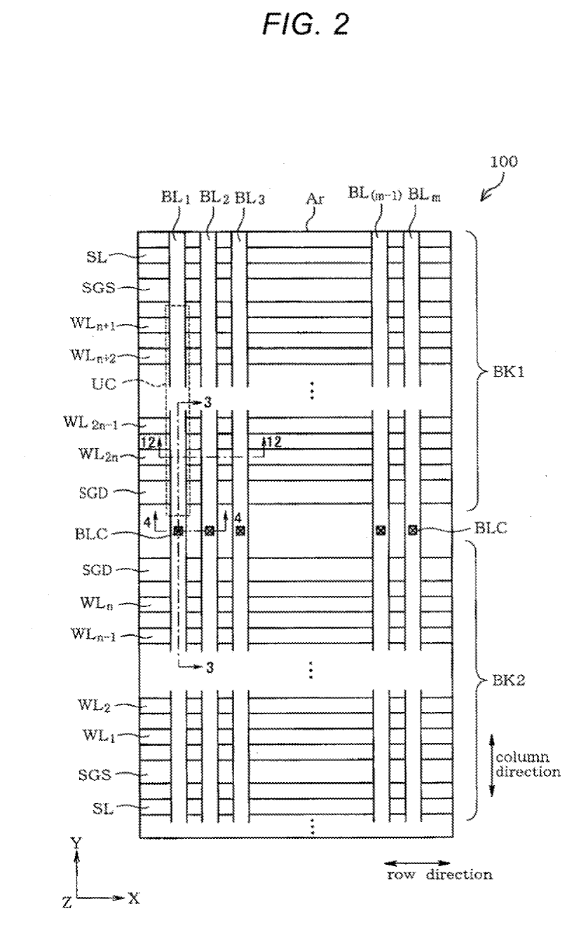

The configuration of a NAND type flash memory device is explained with reference to FIG. 1 and FIG. 2. FIG. 1 shows one example of an equivalent circuit diagram of a cell array region of the NAND type flash memory device. FIG. 2 shows one example of a plan view of the cell array region of the NAND type flash memory device.

As shown in FIG. 1, a NAND type flash memory device 100 includes a cell array region Ar. The cell array region Ar has a plurality of blocks BK1, BK2 . . . adjacently disposed in the Y direction (column direction) in the drawing. Each of the plurality of blocks BK1, BK2 . . . includes a plurality of unit memory cells UC disposed side by side in the X direction (row direction) in the drawing. In this embodiment, two blocks BK1 and BK2 are exemplified for facilitating the understanding of the structure NAND type flash memory device 100.

Each of the plurality of unit memory cells UC includes: a NAND string including a plurality of memory cells MC connected in series; and two selector gate transistors STD, STS which are connected to both ends of the NAND string respectively. One end of the unit memory cell UC is connected to bit lines BL1, BL2, . . . , BLm respectively. The bit lines BL1, BL2, . . . , BLm are connected to a sense amplifier (not shown in the drawing). The other ends of the unit memory cells UC are connected to a source line SL in common. Hereinafter, “BL1, BL2, . . . ” are used when individual bit lines BL are to be indicated, and “BL” is used when bit lines are to be indicated without specifying individual bit lines.

The unit memory cell UC includes the plurality of memory cells MC. A gate electrode of each memory cell MC is electrically connected to a word line WL. A control line SGD in each unit memory cell UC is electrically connected to a gate electrode of the select gate transistor STD on a drain side (on a side connected to the bit line) thereof. A control line SGS in each unit memory cell is electrically connected to a gate electrode of the select gate transistor STS on a source line side thereof (on a side connected to the source line).

As shown in FIG. 2, in the cell array region Ar, the source lines SL, the control lines SGS, SGD, and the word lines WL extend in the X direction (row direction) in the drawing, and are disposed parallel to each other in the Y direction (column direction) in the drawing in a spaced-apart manner. The bit lines BL extend in the Y direction (column direction) in the drawing, and are disposed parallel to each other in the X direction (row direction) in the drawing in a spaced-apart manner. Element regions are formed on a semiconductor substrate 10 underneath the bit lines BL (in the Z direction in the drawing, and also in the depth direction from a surface of the paper on which the Figure is drawn), and element separation regions are provided such that each element separation region is formed between adjacent element regions (not shown in the drawing). That is, the semiconductor substrate 10 is separated into the plurality of element regions by the element separation regions.

The memory cell MC is disposed at an intersection of the word line WL and the bit line BL. The select gate transistor STD is disposed at an intersection of the bit line BL and the control line SGD, and the select gate transistor STS is disposed at an intersection of the bit line BL and the control line SGS. A bit line contact BLC is disposed on the bit line BL between the control lines SGD of the blocks BK1, BK2 disposed adjacent to each other.

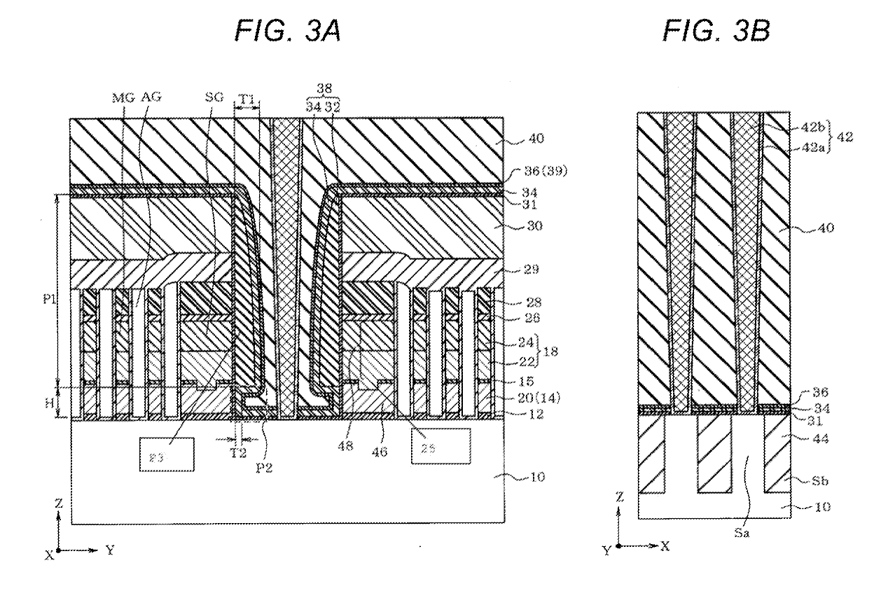

FIG. 3A is one example of a longitudinal cross-sectional view taken along a line 3-3 in FIG. 2. FIG. 3B is one example of a longitudinal cross-sectional view taken along a line 4-4 in FIG. 2. Although the explanation is made by exemplifying a longitudinal cross-sectional view on a bit line contact side in this embodiment, this structure is also applicable to a source line side in the same manner.

FIG. 3A shows the configuration of a portion of the memory cell region showing the memory gates MG of the memory cell transistors MT and the select gate transistor STD on a drain side and a contact region of the select gate transistor STD. The structure of the select gate transistor STS on a source line side of a cell unit UC is also substantially equal to the structure of the select gate transistor STD on a drain side as explained hereinafter.

In FIG. 3A, the upper surface of the semiconductor substrate 10 corresponds to an element region Sa (see FIG. 3B). A silicon substrate may be used as the semiconductor substrate 10, for example. Memory gates MG of the memory cell transistors MT and select gate electrodes SG of the select gate transistors STD are formed on the semiconductor substrate 10.

The memory gate MG of the memory cell transistor MT is formed by stacking an electric charge storage layer 14, an inter-electrode insulating film 15, and a control gate electrode 18 on agate insulating film 12 in this order. The gate insulating film 12 is a silicon oxide film, for example. The electric charge storage layer 14 is formed of a first polycrystalline silicon film 20 into which a dopant is implanted, for example. For example, boron is implanted into the first polycrystalline silicon film 20 as a dopant so that a conductive type of the first polycrystalline silicon film 20 is a p type.

The inter-electrode insulating film 15 is formed of an ONO (oxide-nitride-oxide) film, an NONON (nitride-oxide-nitride-oxide-nitride) film, an insulating film having high dielectric constant or the like, for example. The control gate electrode 18 is formed of a multilayer film including a second polycrystalline silicon film 22 doped with a dopant and a metal film 24 made of tungsten or the like. For example, boron is implanted into the second polycrystalline silicon film 22 as a dopant so that a conductive type of the second polycrystalline silicon film 22 is a p type. The electric charge storage layer 14 and the control gate electrode 18 are insulated from each other by the inter-electrode insulating film 15.

The memory cell transistor MT includes the memory gates MG formed on the semiconductor substrate 10. The select gate transistor STD is disposed adjacent to the memory cell transistor MT positioned at one end of the unit memory cell UC, i.e., at the end of a NAND string.

The select gate electrode SG of the select gate transistor STD has a film layer structure substantially the same as the film layer structure of the memory gate MG of the memory cell transistor MT. The select gate electrode SG has the structure where the first polycrystalline silicon film 20, the inter-electrode insulating film 15, the second polycrystalline silicon film 22 and the metal film 24 are layered on the gate insulating film 12. The first polycrystalline silicon film 20 is a film corresponding to the electric charge storage layer 14 in the memory gate MG (hereinafter referred to as “lower electrode film 46”), and the second polycrystalline silicon film 22 and the metal film 24 are films corresponding to the control gate electrode 18 in the memory gate MG (hereinafter referred to as “upper electrode film 48”).

For example, boron is implanted into the first polycrystalline silicon film 20 and the second polycrystalline silicon film 22 as a dopant as described above so that a conductive type of the first polycrystalline silicon film 20 and the second polycrystalline silicon film 22 is a p type. The upper electrode film 46 and the lower electrode film 48 are connected to each other through an opening portion 25 formed in the inter-electrode insulating film 15 so that the upper electrode film 46 and the lower electrode film 48 are brought into an electrically connected state. Due to such a configuration, the select gate transistor STD functions as a normal transistor. A first cap insulating film 26 and a second cap insulating film 28 are formed on the metal film 24. A silicon nitride film may be used as the first cap insulating film 26, for example. A silicon oxide film may be used as the second cap insulating film 28, for example.

A source/drain region (not shown in the drawing) is formed on a surface layer of the semiconductor substrate 10 at a position between the memory gates MG and a position between the memory gate MG and the selection gate electrode SG. For example, phosphorus is implanted into the source/drain region as a dopant.

A source/drain region (not shown in the drawing) having the LDD (lightly doped drain) structure is formed on the front layer of the semiconductor substrate 10 at a position between the select gate electrodes SG disposed adjacent to each other.

An air gap AG is formed between the memory gates MG and between the memory gate MG and the select gate electrode SG. A first insulating film 29 is formed over the memory gates MG, the select gate electrode SG and the air gaps AG such that the first insulating film 29 covers the air gaps AG from above. A second insulating film 30 is formed on the first insulating film 29. The first insulating film 29 and the second insulating film 30 are formed of a silicon oxide film, for example. A third insulating film 31 is formed so as to cover an upper surface of the second insulating film 30, side surfaces of the second insulating film 30, side surfaces of the first insulating film 29 and side surfaces of the select gate electrode SG. The third insulating film 31 is formed of a silicon oxide film, for example.

A side wall insulating film 32 is formed on the portion of the third insulating film 31 on the side surface of the select gate electrodes SG on a side where the select gate electrodes SG face each other, that is, on a side where the air gaps AG are not formed. The side wall insulating film 32 is formed of a silicon oxide film, for example. A first liner film 34 and a second liner film 36 are formed so as to cover the second insulating film 30, the third insulating film 31 and the side wall insulating film 32.

The side wall insulating film 32 is formed on only a portion of the side surface of the select gate electrode SG. The side wall insulating film 32 is not formed on a lower portion of the side surface of the select gate electrode SG, such that a space exists between the lowest surface of the side wall insulating film 32 and the adjacent surface of the third insulating film 31. The first liner film 34 is formed so as to cover a surface of the side wall insulating film 32 and the exposed surface of the selection gate electrode SG between the lowest surface of the side wall insulating film 32 and the adjacent surface of the third insulating film 31. The side wall insulating film 32 and the first liner film 34 are collectively referred to as a first spacer 38. A silicon oxide film having film quality with lower density may be used as the side wall insulating film 32, for example. A silicon oxide film having film quality with higher density may be used as the first liner film 34, for example.

A surface of the first spacer 38 is further covered with a second liner film 36. The second liner film 36 is referred to as a second spacer 39. The second liner film 36 is formed of a silicon nitride film, for example.

An interlayer insulating film 40 is formed on the second liner film 36 such that the interlayer insulating film 40 is filled in a recessed portion (trench portion) between the select gate electrodes SG, and it overlies the memory gates MG and an upper surface of the select gate electrode SG. Contact plugs 42 are formed such that each contact plug 42 extends through the interlayer insulating film 40 from an upper portion to a lower portion thereof, further extends through the second liner film 36, the first liner film 34 and the third insulating film 31, and reaches the semiconductor substrate 10 in a region adjacent to the select gate electrode SG. The contact plug 42 is formed of a layered film including a barrier film 42a and a metal film 42b, and a silicide layer is formed at an interface between the contact plug 42 and the semiconductor substrate 10.

In this embodiment, as described hereinafter, on the side surface of the select gate electrode SG, the first spacer 38 (the multilayer film including the side wall insulating film 32 and the first liner film 34) is further divided into two portions. That is, a portion of the first spacer 38 which corresponds to the side wall of the select gate electrode SG and on which the side wall insulating film 32 and the first liner film 34 are layered is referred to as a first portion P1. On the side surface of the select gate electrode SG, a portion of the first spacer 38 where the side wall insulating film 32 is not formed on the side wall of the selection gate electrode SG, that is, the portion of the first spacer 38 disposed below the side wall insulating film 32 where the first spacer 38 is formed of a single layer of the first liner film 34 is referred to as a second portion P2. Assume a height of the second portion P2 as “H”. The height H of the second portion P2 is a distance from an upper surface of the third insulating film 31 to a lower surface of the side wall insulating film 32 in the second portion P2. The lower surface of the side wall insulating film 32 is located at a position higher than an upper surface of the semiconductor substrate 10.

The first spacer 38 forms a recessed shape (it is indented) in the lateral direction (Y direction in the drawing). Such a recessed portion has a U-shape, for example. The first portion P1 of the first spacer 38 is formed of a layered film including the side wall insulating film 32 and the first liner film 34. The second portion P2 of the first spacer 38 is formed of a single-layered film of the first liner film 34. Accordingly, a film thickness (width) T1 of the first portion P1 of the first spacer 38 in the lateral direction (Y direction in the drawing) is larger than a film thickness (width) T2 of the second portion P2 of the first spacer 38 in the lateral direction (Y direction in the drawing).

FIG. 3B shows one example of the longitudinal cross-sectional view of the portion of the memory cell region orthogonal to the above-mentioned cross-sectional view shown in FIG. 3A. In FIG. 3B, element regions Sa are separated from each other in the lateral direction (X direction in the drawing) by element separation regions Sb. An element separating insulating film 44 is embedded in the element separation regions Sb. Upper surfaces of the element regions Sa and upper surfaces of the element separation regions Sb are flat and generally co-planar, i.e., flush with each other, and the first liner film 34, the second liner film 36 and the interlayer insulating film 40 are formed on portions of the element regions Sa and on the adjacent surface of the element separation regions Sb. The contact plugs 42 are formed such that each contact plug 42 penetrates the interlayer insulating film 40, the second liner film 36 and the first liner film 34 from an upper surface of the interlayer insulating film 40 and is connected to a surface of the element region Sa.

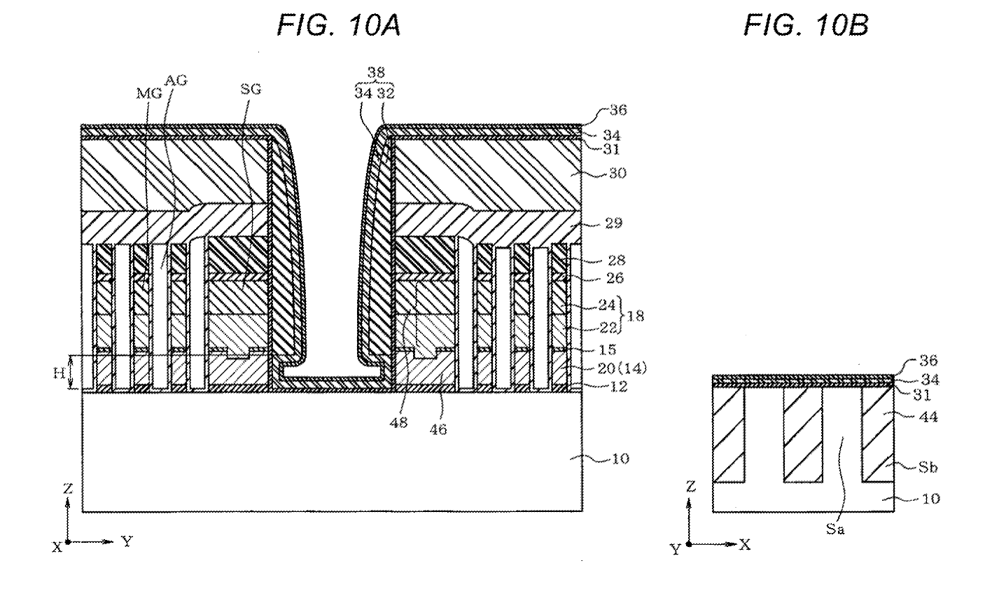

Next, a method of manufacturing the NAND type flash memory device according to the embodiment is explained with reference to FIG. 3A, FIG. 3B to FIG. 10A, FIG. 10B. FIG. 3A to FIG. 10A show one example of a longitudinal cross-sectional view taken along a line 3-3 of FIG. 2. FIG. 3B to FIG. 10B show one example of a longitudinal cross-sectional view taken along a line 4-4 in FIG. 2. The longitudinal cross-sectional view corresponds to a region between the select gate electrodes SG, and in the “A” sections, adjacent memory cells MT and memory gates MG.

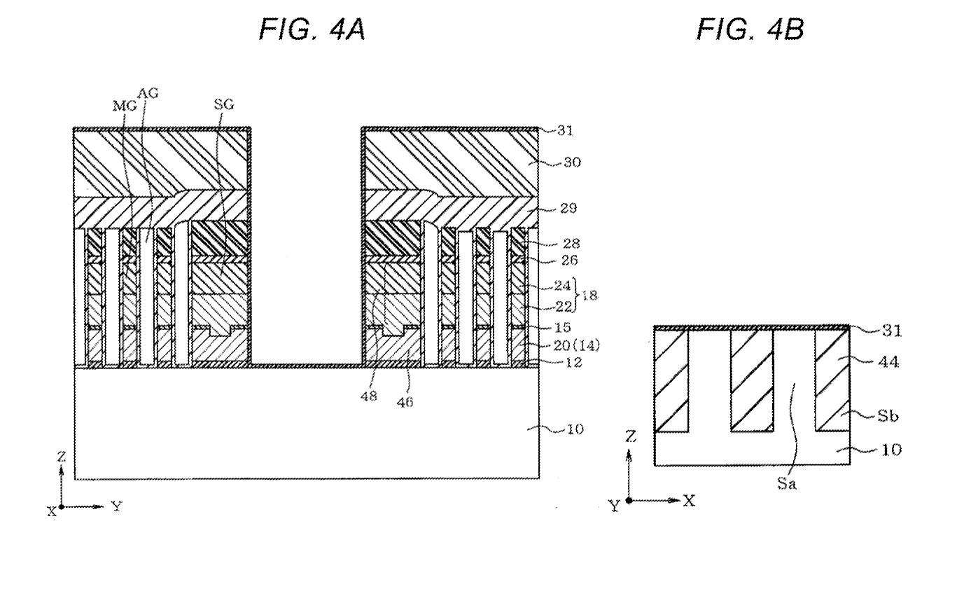

Firstly, as shown in FIG. 4A and FIG. 4B, element separation regions Sb and memory gates MG are formed on a semiconductor substrate 10. An element separating insulating film 44 is filled into trenches formed in the element separation regions Sb and processed to yield an upper surface flush with the tops of the element regions Sa. The portion of the semiconductor substrate between the element separation regions Sb configures an element region Sa. The element separating insulating film 44 is formed of a silicon oxide film, for example. The silicon oxide film may be formed by applying polysilazane to the semiconductor substrate 10 by coating and by applying heat treatment to polysilazane, for example. The memory gate MG includes an electric charge storage layer 14, an inter-electrode insulating film 15, and a control gate electrode 18. The selection gate electrode SG includes a lower electrode film 46, an inter-electrode insulating film 15 and an upper electrode film 48. The electric charge storage layer 14 and the lower electrode film 46 are formed of a first polycrystalline silicon film 20. The first polycrystalline silicon film 20 may be formed by a CVD (Chemical Vapor Deposition) method, for example. The inter-electrode insulating film 15 is formed of an ONO (Oxide Nitride Oxide) film which is a layered film formed of a silicon oxide film, a silicon nitride film and a silicon oxide film, for example. The silicon oxide film and the silicon nitride film may be formed by a CVD method, for example. The control gate electrode 18 and the upper electrode film 48 are formed by layering a second polycrystalline silicon film 22 and a metal film 24 respectively. The second polycrystalline silicon film 22 may be formed by a CVD method, for example. Tungsten may be used as a material for forming the metal film 24, for example, and the metal film 24 may be formed by a sputtering method, for example. The barrier film may be further formed below the metal film 24. Tungsten nitride (WN) may be used as a material for forming the barrier film, for example, and the barrier film may be formed by a sputtering method, for example. A first cap insulating film 26 and a second cap insulating film 28 are formed on the metal film 24. A silicon nitride film may be used as the first cap insulating film 26, for example. A silicon oxide film may be used as the second cap insulating film 28, for example. The silicon nitride film and the silicon oxide film may be formed by a CVD method, for example. The layered film is patterned using a lithography method and an RIE (Reactive Ion Etching) method. By such patterning, a portion of the layered films between the memory gates MG and a portion of the layered films between the memory gate MG and the select gate electrode SG are etched so that the memory gates MG are separated from each other and the memory gate MG and the select gate electrode SG are separated from each other by etching. Due to such etching, the memory gates MG are formed.

The first insulating film 29 is formed on the memory gates MG and the select gate electrodes SG. The first insulating film 29 is formed of a silicon oxide film, for example. The first insulating film 29 may be formed by a CVD method under a low step coverage condition, for example. Accordingly, the first insulating film 29 may be formed so as to cover upper portions of the memory gates MG and the selection gate electrode SG without filling into spaces formed between the memory gates MG and spaces formed between the memory gate MG and the select gate electrode SG and hence, air gaps AG may be formed. The air gap AG is formed between the memory gates MG and between the memory gate MG and the select gate electrode SG. Next, the second insulating film 30 is formed. The second insulating film 30 is formed of a silicon oxide film, for example. The silicon oxide film may be formed by a CVD method, for example. Next, the films are processed by a lithography method and an RIE method such that the select gate electrodes SG located adjacent to each other are separated from each other. In such a step, the films ranging from the second insulating film 30 to the first polycrystalline silicon film 20 are removed in regions corresponding to spaces between the selection gate electrodes SG. Next, a third insulating film 31 is formed. The third insulating film 31 is formed of a silicon oxide film, for example. The silicon oxide film may be formed by a CVD method, for example. The structure shown in FIG. 4A and FIG. 4B is formed by these steps.

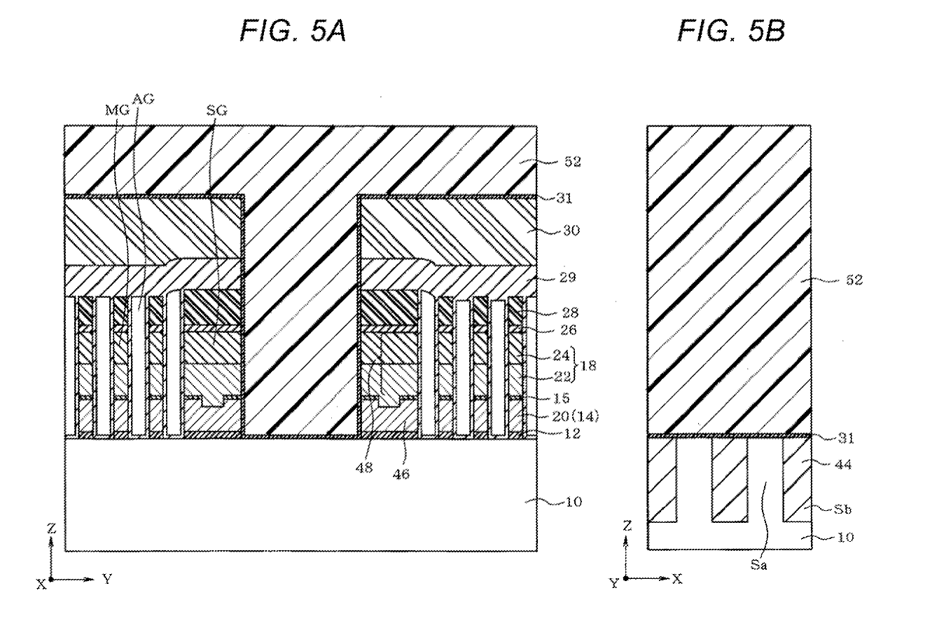

Next, as shown in FIG. 5A and FIG. 5B, a resist 52 is coated over the third insulating film 31 over the whole surface of the semiconductor substrate 10. The resist 52 is formed so as to fill gaps formed between the selection gate electrodes SG.

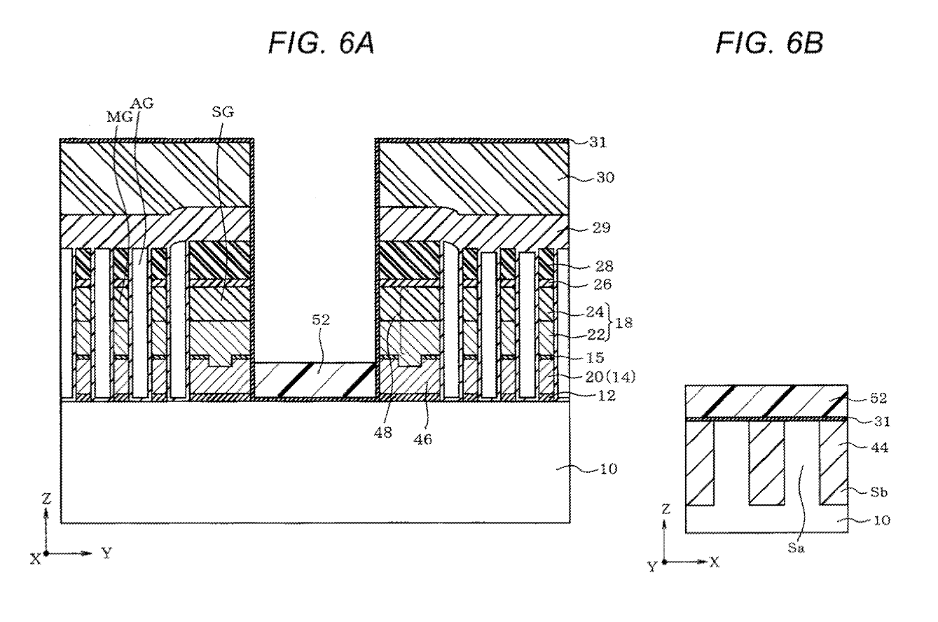

Next, as shown in FIG. 6A and FIG. 6B, the resist 52 is etched back by an RIE method, for example. Due to such etching-back, an upper surface of the resist 52 is removed, and a portion of the resist 52 having a predetermined film thickness equal to the height H of the second portion P2 remains on a bottom portion of a trench between the select gate electrodes SG.

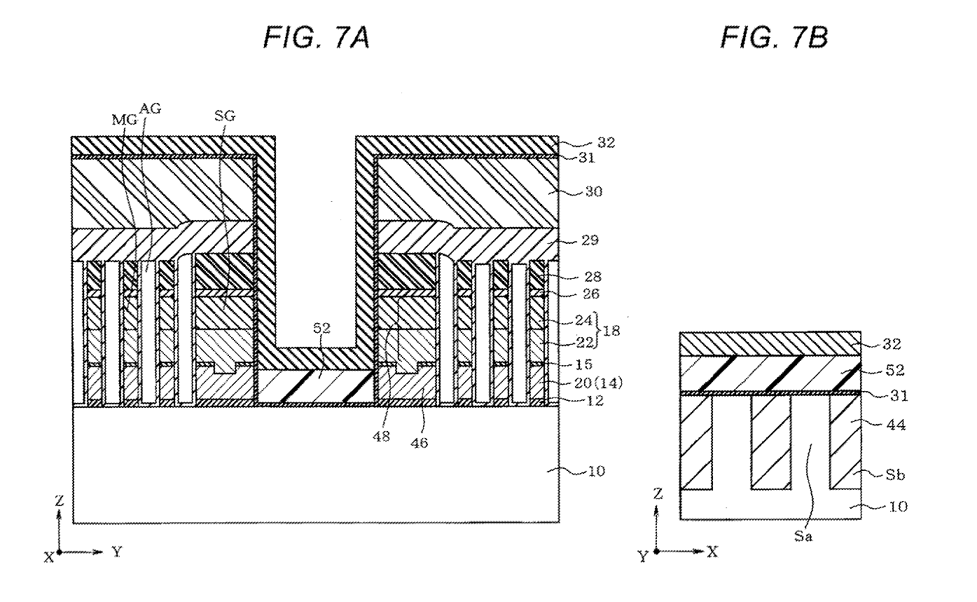

Next, as shown in FIG. 7A and FIG. 7B, a side wall insulating film 32 is formed to cover an upper surface of the portion of the resist 52 remaining in the base of the opening, the inner surfaces of the trenches formed between the selection gate electrodes SG, and the upper surface of the third insulating film 31 formed on the second insulating film 30. A silicon oxide film may be used as the side wall insulating film 32, for example. The silicon oxide film may be formed by a room temperature CVD method which may be carried out at a room temperature, for example, and is formed under a condition where the silicon oxide film is formed conformally, i.e., it has a relatively uniform thickness over the entire deposited surface. By forming the silicon oxide film by the room temperature CVD method, the silicon oxide film may be formed on the resist 52 without disturbing or causing removal of the remaining resist 52.

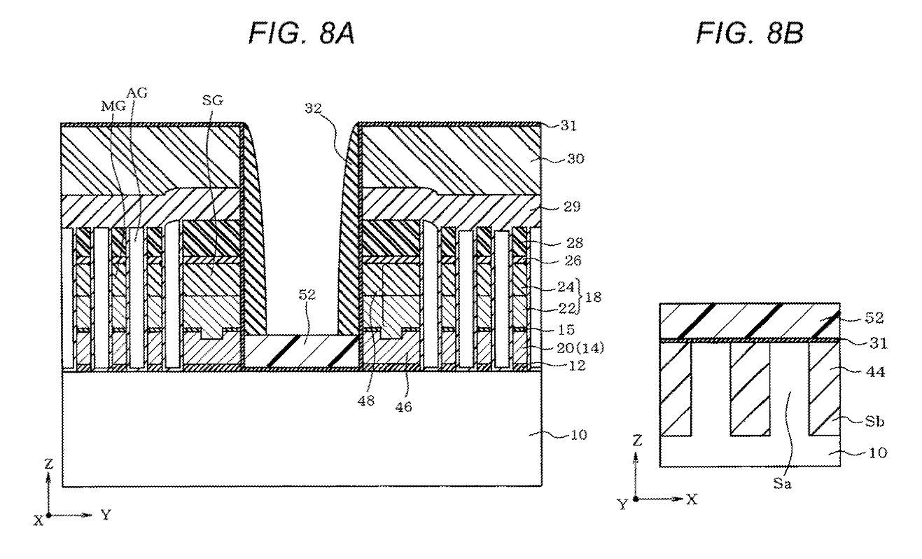

Next, as shown in FIG. 8A and FIG. 8B, the side wall insulating film 32 is etched back using an RIE method under an anisotropic condition thus forming the side wall insulating film on the side surface portions between the selection gate electrodes SG disposed adjacent to each other. Due to such processing, a portion of the side wall insulating film 32 on the resist 52 is removed so that a surface of the resist 52 is exposed. In such an etching-back step, the surface of the third insulating film 31 on the semiconductor substrate 10 (element region Sa) in the opening, the underlying semiconductor substrate 10 and surfaces of the element separating insulating films 44 (element separation regions Sb) between the select gate electrodes SG disposed adjacent to each other are covered by the resist 52 so that it is possible to prevent the surface of the semiconductor substrate 10 and the surfaces of the element separating insulating films 44 from being exposed to etching atmosphere. Accordingly, it is possible to prevent the phenomenon where the upper portions of the element separating insulating films 44 are removed and an indentation (recessed portion) is formed in the surfaces of the element separation regions Sb. It is also possible to prevent a phenomenon that an upper portion of the semiconductor substrate 10 is removed so that surfaces of the element regions Sa (semiconductor substrate 10) are retracted inwardly thereof between the element separation regions Sb. It is also possible to prevent the surface of the semiconductor substrate 10 from being damaged by etching. For example, in converting the material of the contact plug 42 at the contact location thereof with the semiconductor substrate, it is possible to prevent the abnormal formation of silicide. When the silicide is formed abnormally, there exists a possibility that a leakage or an open circuit occurs at the contact portion. However, this processing may prevent the occurrence of such leakage or open circuit.

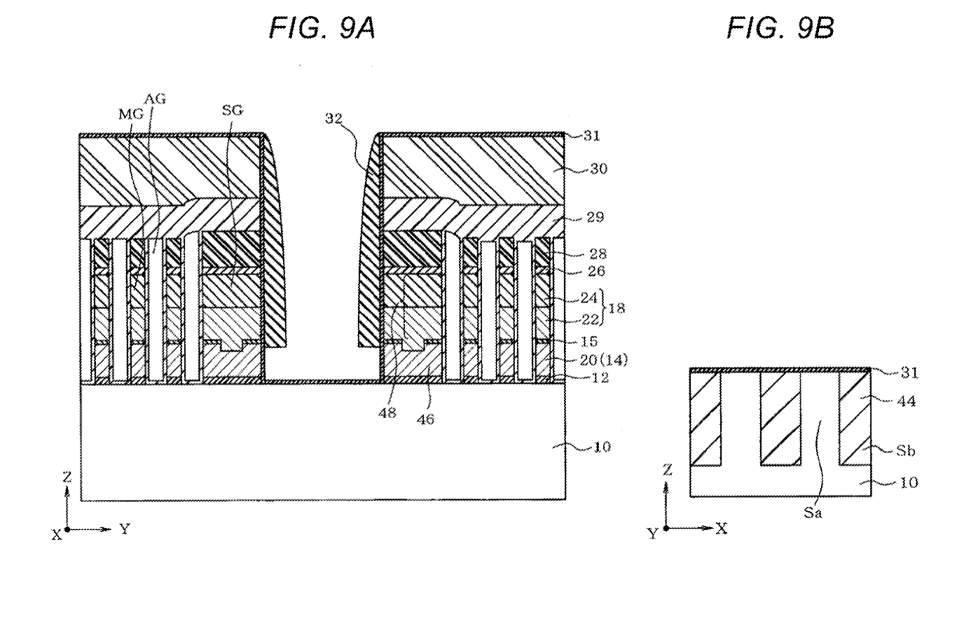

Next, as shown in FIG. 9A and FIG. 9B, the resist 52 is removed. The resist 52 may be removed by an asking process using an oxygen plasma, for example. By performing the above-mentioned steps, the side wall insulating film 32 is thus formed only on the side surfaces of the select gate electrodes SG disposed adjacent to each other. The side wall insulating film 32 extends on the third insulating film 31 over the side surfaces of the second insulating film 30, side surfaces of the first insulating film 29 and side surfaces of the adjacent select gate electrodes SG. However, the side wall insulating film 32 is not formed on lower portions of the side surfaces of the selection gate electrodes SG so that lower surfaces of the side wall insulating film 32 are spaced from a surface of the semiconductor substrate 10. That is, recessed portions are formed below the side wall insulating film 32 in the lateral direction (Y direction in the drawing), and the recessed portions have an eave or overhang shape.

Next, as shown in FIG. 10A and FIG. 10B, a first liner film 34 and a second liner film 36 are formed sequentially. The first liner film 34 may be formed of a silicon oxide film, for example. The second liner film 36 may be formed of a silicon nitride film, for example. The silicon oxide film and the silicon nitride film may be formed by a CVD method, for example. In this embodiment, the first liner film 34 is formed such that the recessed portion below the side wall insulating film 32 is not completely filled with the first liner film 34 and second liner film 36. That is, assuming a height of the recessed portion below the side wall insulating film 32 as “H”, the height H is twice or more as large as a film thickness of the first liner film 34. Accordingly, a recessed shape extending inwardly of the first liner film 34 below the side wall insulating film 32 remains.

Next, as shown in FIG. 3A and FIG. 3B, an interlayer insulating film 40 is formed, holes extending though the interlayer insulating film and reaching the surface of the semiconductor substrate 10 are formed from an upper surface of the interlayer insulating film 40 by a lithography method and an RIE method, and a metal film is filled in the holes thus forming contact plugs 42. The contact plug 42 may be formed of a layered film including a barrier film 42a and a metal film 42b, for example. The barrier film 42a may be formed using titanium nitride (TiN), for example. The metal film 42b may be formed using tungsten (W), for example. The barrier film 42a made of titanium nitride and the metal film 42b made of tungsten may be formed by a CVD method, for example. By applying heat treatment after the contact plugs 42 are formed, silicide is formed on an interface between the barrier film 42a and the semiconductor substrate 10. The NAND type flash memory device according to this embodiment may be formed by these steps.

As has been explained above, according to this embodiment, during etching of the side wall insulating film 32 explained with reference to FIG. 8A and FIG. 8B, the bottom portion of the trench between the selection gate electrodes SG is covered with the resist 52. Accordingly, it is possible to prevent the surface of the semiconductor substrate 10 and the surfaces of the element separating insulating films 44 from being exposed to an etch environment and thus to the etch chemistry.

Accordingly, in the etching, it is possible to prevent the formation of an etched recess (indentation) on surfaces of the element separation regions Sb (element separating insulating films 44) during etching of the sidewall insulation film 32. Accordingly, it is possible to prevent the occurrence of a state where the third liner film 36 or the like is formed in a recess in the element separation regions Sb so that a stress is generated whereby crystal defects occur in the semiconductor substrate 10.

Further, it is possible to prevent a phenomenon that the surface of the semiconductor substrate 10 in the element regions Sa are recessed due to etching of the semiconductor substrate 10 (element region Sa) during etching of the sidewall insulation film 32. If this were to occur, the first liner film 34 would contact and directly contact and cover the element region Sa, and when the contact holes are etched based on a time of etching, the contact hole may not penetrate the first liner film 34 and second liner film 36 and an open circuit defect will occur because the contact plug 42 will not contact the element region Sa, but have an insulator disposed between the base of the contact plug and the element region Sa. Accordingly, the occurrence of an open-circuit defect at the contact plug 42 may be prevented. It is also possible to prevent the surface of the semiconductor substrate 10 from being damaged due to etching. Accordingly, in forming a silicide layer at a lower portion of the contact plug 42, it is possible to prevent silicide from being formed abnormally and hence, it is possible to prevent the occurrence of a leakage or an open circuit at the contact.

### First Modification

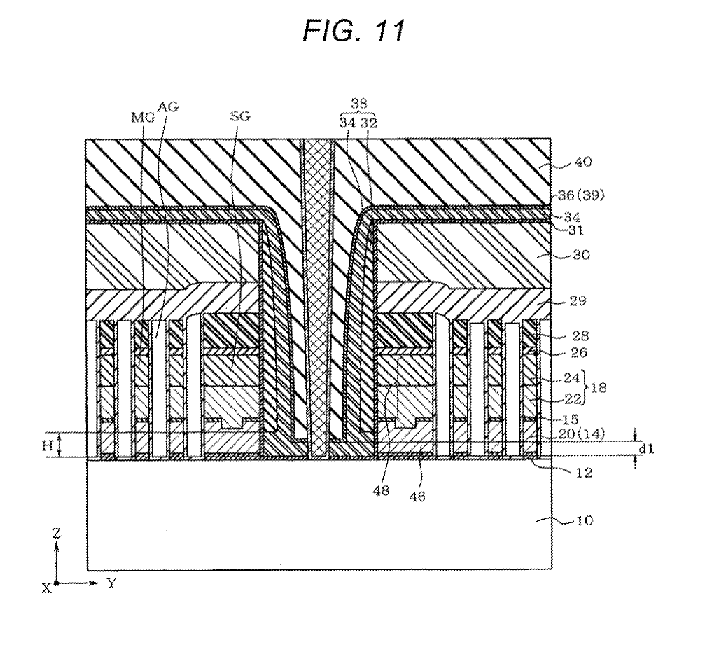

FIG. 11 shows a first modification of the embodiment. In the first modification, a recessed portion below a side wall insulating film 32 is filled with a first liner film 34. That is, assuming a height of the recessed portion below the side wall insulating film 32 as “H”, the height H is set lower than twice a film thickness dl of the first liner film 34. Due to such setting of the height H, the recessed portion below the side wall insulating film 32 is filled with the first liner film 34. In this modification, the film thickness dl is a distance from an upper surface of the third insulating film 31 to a lower surface of the second liner film 36. The first modification may acquire the substantially same advantageous effects as the embodiment.

### Second Modification

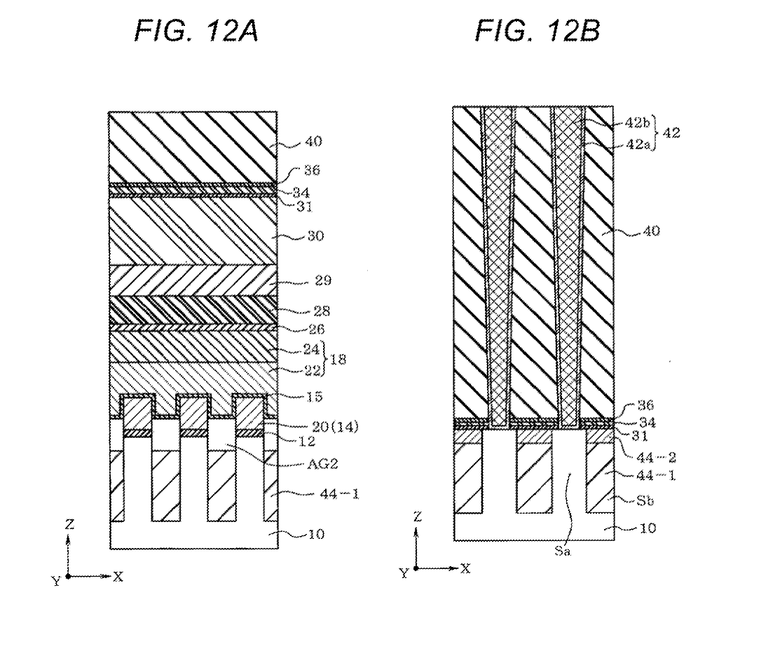

FIG. 12A and FIG. 12B show a second modification of the embodiment. FIG. 12A shows one example of a longitudinal cross-sectional view taken along a line 12-12 in FIG. 2, and FIG. 12B shows one example of a longitudinal cross-sectional view taken along a line 4-4 in FIG. 2. FIG. 12A shows the structure of a region where a word line WL is formed in the memory cell region. In the second modification, second air gaps AG2 are formed by removing the upper portions 44-2 of the element separating insulating films 44 below the word line WL (memory gate MG). In this modification, to selectively remove the upper portions of the element separating insulating films 44, these films may be formed such that the etching rate of the upper portion 44-2 of the element separating insulating film 44 is greater than the etching rate of the lower portion 44-1 of the element separating insulating film 44 by setting a film quality of a silicon oxide film for forming the upper portion 44-2 of the element separating insulating film 44 lower than a film quality of a silicon oxide film for forming the lower portion 44-1 of the element separating insulating film 44.

In this case, as shown in FIG. 12B, the upper portion 44-2 of the element separating insulating film 44 between control lines SGD is not removed. Accordingly, also between the select gate electrodes SG, the thickness of the upper portion 44-2 of the element separating insulating film 44 is easily decreased by etching. Accordingly, when the upper portion 44-2 of the element separating insulating film 44 is exposed to etching atmosphere, an indentation is easily formed on the element separating insulating film 44. According to this embodiment, however, a surface of the element separating insulating film 44 between select gate electrodes SG is covered with a resist 52 and hence, the formation of the indentation on the element separating insulating film 44 may be suppressed. The second modification where the indentation is easily formed on the element separating insulating film 44 have the advantageous effect of preventing the formation of an indentation on the upper portion of the element separating insulating film 44 than other embodiments and modifications.

### Other Embodiments

In the above-mentioned embodiment, an example where the present disclosure is applied to the NAND type flash memory device is described. However, the present disclosure is also applicable to a semiconductor memory device such as an NOR type flash memory device or an EPROM, a semiconductor memory device such as a DRAM or an SRAM, or a logic semiconductor device such as a microcomputer besides the NAND type flash memory device.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a semiconductor substrate;
a plurality of NAND strings each of which includes a plurality of memory cells provided on the semiconductor substrate and disposed in a first direction, and a select gate provided adjacent to the memory cell at an end portion of the plurality of memory cells, such that two select gates face each other at the ends of their respective memory cells; and
a first spacer layer formed on a side wall between the select gates of the NAND strings disposed adjacent to each other, wherein
the first spacer layer includes a recess therein at the portion thereof located adjacent to the semiconductor substrate.

2. The semiconductor memory device according to claim 1, further comprising:
a second spacer layer, a first portion of the second spacer layer being located over the first spacer layer, and a second portion of the second spacer layer also being located on a side surface of a lower portion of the select gate within the recess.

3. The semiconductor memory device according to claim 2, wherein
the second spacer layer has a U-shape in section in the region between the first spacer layer and the substrate.

4. The semiconductor memory device according to claim 2, wherein
a first insulating layer is disposed over the substrate in the location between the adjacent select gates, and the distance between the surface of the first insulating film facing the recess and the surface of the first spacer layer facing the recess is over twice as large as a film thickness of the second film.

5. The semiconductor memory device according to claim 2, wherein
the first spacer layer is formed using a first material, the second spacer layer is formed using a second material, and the density of the second material is greater than the density of the first material.

6. The semiconductor memory device according to claim 2, further comprising:
a third spacer layer covering the second spacer layer.

7. The semiconductor memory device according to claim 6, wherein
the second spacer layer is conformally formed over the surfaces of the first spacer layer and on a side wall of a lower portion of the selection gate.

8. The semiconductor memory device according to claim 2, wherein
the lower surface of the first spacer layer is disposed at a position above the upper surface of the semiconductor substrate in the area between adjacent selector gates.

9. The semiconductor memory device according to claim 1, further comprising:
element separation regions extending inwardly of the semiconductor substrate; and
an element separating insulating film formed in the element separation regions extending into the semiconductor substrate, wherein
the memory cell includes a gate electrode, and
an air gap is formed between the element separating insulating film and the gate electrode.

10. The semiconductor memory device according to claim 9, wherein
the element separating insulating film includes,
a third portion, and
a fourth portion formed on the third portion and formed of a material having lower density than a material forming the third portion.

11. A semiconductor memory device comprising:
a semiconductor substrate;
a plurality of NAND strings each of which includes a plurality of memory cells provided on the semiconductor substrate and disposed in a first direction, and a select gate provided adjacent to the memory cell located at an outermost end portion of the plurality of memory cells, such that the select gates of the NAND strings are disposed adjacent to each other with a gap formed therebetween; and
a first spacer formed on a side wall between the select gates of the NAND strings disposed adjacent to each other, wherein
the first spacer includes: a first film formed of a first material and a second film formed of a material having density higher than density of the first material, and
in a direction of the select gate spaced from the semiconductor substrate, the first spacer includes: a first portion of a layer of the first film and the second film on a side surface of a portion of the select gate at a first distance from the semiconductor substrate; and a second portion excluding the first portion and the including the second film formed extending into a gap between the upper surface of the semiconductor substrate and the first film and on a side surface of the selection gate.

12. The semiconductor memory device according to claim 11, wherein
a lower surface of the first film extends along the side walls of the select gate to a location spaced from the semiconductor substrate in the area between the adjacent select gates.

13. The semiconductor memory device according to claim 11, wherein
the first distance is less than twice as large as the thickness of the second film.

14. The semiconductor memory device according to claim 11, further comprising:
an element separating insulating film formed on the semiconductor substrate, wherein
the memory cell includes a gate electrode, and
an air gap is formed between the element separating insulating film and the adjacent gate electrode.

15. The semiconductor memory device according to claim 14, wherein
the element separating insulating film includes:
a third portion; and
a fourth portion located on the third portion and comprising a material having lower density than the material comprising the third portion.

16. A method of forming a semiconductor device, comprising:
forming at least two gate structures adjacent one another on a first insulating layer on a semiconductor substrate with a space therebetween, such that the sidewalls of the gate structures face one another across the space;
forming a resist layer on the first insulating film located on the semiconductor substrate in the space between the gate structures while leaving exposed the sidewalls of the gate structures;
forming a second insulating layer over the gate structures, the portions of the sidewalls of the gate structures not covered by the resist layer and the resist layer on the first insulating film located on the semiconductor substrate in the space between the gate structures; and
anisotropically etching the second insulating layer to form a first sidewall insulator layer extending along the walls of the gate structures and terminating at the resist layer leaving a space between the first insulating layer and the second insulating layer.

17. The method of claim 16, further comprising:
removing the resist layer on the first insulating film located on the semiconductor substrate between the gate structures and exposing the sidewall of the gate structures in the area between the first insulating layer and the second insulating layer.

18. The method of claim 17, further comprising:
forming a third insulating layer over the second insulating layer and into the space between the first insulating layer and the second insulating layer.

19. The method of claim 18, further comprising:
forming a fourth insulating film in at least the space between the third insulating layers overlying the second insulating layers on the sidewalls of the gate structures;
etching a hole through the fourth insulating film located in the space between the third insulating layers overlying the second insulating layers, and through the first insulating film to the semiconductor substrate; and
filling the hole with a conductive material.

20. The method of claim 16, wherein the resist layer on the first insulating layer located on the semiconductor substrate between the gate structures is formed by coating a resist on the gate structures, the sidewalls of the gate structures and on the first insulating layer, and the resist on the gate structures and the sidewalls of the gate structures is removed to expose the sidewalls of the gate structure at a location spaced from the first insulating layer.
